(19) United States
(12) Patent Application Publication
(10) Pub. No.: US 2026/0121671 A1
(43) Pub. Date: Apr. 30, 2026

(54) APPARATUS AND METHODS FOR DIGITAL PRE-DISTORTION FOR A POWER AMPLIFIER

(71) Applicant: Silicon Laboratories Inc., Austin, TX (US)

(72) Inventors: John Khoury, Austin, TX (US); Mustafa Koroglu, Austin, TX (US); Aslamali Rafi, Austin, TX (US)

(21) Appl. No.: 18/932,948

(22) Filed: Oct. 31, 2024

(51) Int. Cl. H04B 1/04

(52) U.S. Cl. CPC H04B 1/0475; H04B 2001/0425

(57) ABSTRACT

In one embodiment, an apparatus includes a baseband processor to generate a baseband signal and a digital pre-distortion (DPD) circuit to pre-distort the baseband signal with compensation information obtained from a lookup table. The lookup table may have a plurality of entries each to store a pre-distortion value, the lookup table to be addressed based on a target output power level of the baseband signal. The apparatus also may include a converter to convert the pre-distorted baseband signal to an analog signal and radio frequency (RF) circuitry comprising: a mixer to upconvert the analog signal to a pre-distorted RF signal, and a power amplifier to amplify the pre-distorted RF signal.

### BACKGROUND

Some wireless transceivers have radio frequency (RF) power amplifiers (PA) that can operate in multiple bands, e.g., at 2.4 GHz and 5 GHZ. Ideally, these PAs are linear amplifiers to amplify and pass RF transmit signals. However, at high power levels, the PA can soft clip due to limited amplifier headroom, causing non-linearities. This soft clipping is a non-linear function that degrades performance. The soft clipping can modify the amplitude and phase of the envelope of the PA output signal. One technique to reduce this non-linearity is to digitally compensate at baseband frequencies by essentially creating an inverse function of the PA by pre-distorting baseband signals. Current implementations of digital pre-distortion (DPD) can incur significant computing time, which can impact the ability to adequately perform DPD when transmitting high speed signals.

### SUMMARY OF THE INVENTION

In one aspect, an apparatus includes: a baseband processor to generate a baseband signal; a digital pre-distortion (DPD) circuit to pre-distort the baseband signal with compensation information obtained from a lookup table, the lookup table having a plurality of entries each to store a pre-distortion value, the lookup table to be addressed based on a target output power level of the baseband signal; a converter to convert the pre-distorted baseband signal to an analog signal; and radio frequency (RF) circuitry. The RF circuitry may include: a mixer to upconvert the analog signal to a pre-distorted RF signal; and a power amplifier (PA) to amplify the pre-distorted RF signal.

In various implementations, each of the plurality of entries of the lookup table is to store the compensation information comprising one of a complex attenuation value or a complex gain value.

In an implementation, the apparatus further comprises an address generator circuit to generate the address based on the target output power level. The address generator circuit is to generate the address comprising a sum of a first portion and a second portion. The address generation circuit is to: generate the first portion based on a first comparison of the target output power level to a first value; and generate the second portion based on a second comparison of a result of an operation between the target output power level and the first portion to a second value.

In an implementation, the apparatus further comprises at least one counter to maintain a count of samples of the baseband signal having the target output power level that exceeds at least one threshold. The apparatus also may include a control circuit to control a gain level of transmit circuitry of the RF circuit based at least in part on the count. The apparatus may also include a loopback circuit coupled to an output of the PA, the loopback circuit to generate a digital signal corresponding to the amplified RF signal.

In an implementation, the loopback circuit further comprises an alignment circuit to receive the digital signal and the pre-distorted baseband signal and to align the pre-distorted baseband signal with the digital signal. In an implementation, the alignment circuit comprises: an integer alignment circuit; a fractional alignment circuit; and a gain/phase alignment circuit. The alignment circuit may include at least one correlator, each of the integer alignment circuit, the fractional alignment circuit and the gain/phase alignment circuit to share the at least one correlator.

In an implementation, each of the plurality of entries is associated with the target output power level that is logarithmically spaced from adjacent entries.

In an implementation, the DPD circuit is to further pre-distort the baseband signal to compensate for a memory effect of the PA.

In another aspect, a method includes: computing, in a digital pre-distortion circuit of a transmitter, an input power of an input sample of a packet to be amplified and output from a PA of the transmitter; determining a target output power for the input sample based on the input power; generating an address based on the target output power and accessing an entry in a lookup table using the address, the entry comprising a PA complex attenuation value associated with the target output power; pre-distorting the input sample using the PA complex attenuation value; upconverting the pre-distorted input sample to a RF signal corresponding to the input sample; and amplifying the RF signal via the PA to output an amplified RF signal.

In an implementation, generating the address comprises: determining a first portion of the address according to a first decoding; determining a second portion of the address according to a second decoding; and combining the first portion and the second portion to generate the address.

In an implementation, the method further comprises accessing a second entry in the lookup table using the address, where the second entry is adjacent to the first entry. The method also may include: determining an interpolated PA complex attenuation value based on the PA complex attenuation value of the entry and a second PA complex attenuation value of the second entry; and pre-distorting the input sample using the interpolated PA complex attenuation value.

In yet another aspect, a method comprises: calculating an attenuation value for a sample pair comprising an input sample to a PA of a transceiver and an output sample from the PA, the output sample aligned with the input sample; computing an output power level of the PA based at least in part on the input sample; generating a PA attenuation value based at least in part on the calculated attenuation value; and storing the PA attenuation value in an entry of a memory, the entry associated with the output power level.

In an implementation, generating the PA attenuation value comprises combining the calculated attenuation value with a stored attenuation value stored in the entry of the memory. The method may further include aligning the input sample with the output sample. aligning the input signal with the output signal comprises: integer aligning the input sample with the output sample; fractionally aligning the input sample with the output sample; and aligning the input sample with the output sample in at least one of gain or phase.

In an implementation, the method comprises: updating a plurality of entries of the memory during transmission of a first packet from the transceiver; and accessing one or more of the updated plurality of entries of the memory to provide digital pre-distortion to one or more samples of a second packet to be transmitted from the transceiver.

In an implementation, the method further comprises calculating the attenuation value, computing the output power level, and generating the PA attenuation value when a change in at least one environmental metric of the transceiver exceeds a threshold.

### BRIEF DESCRIPTION OF THE DRAWINGS

FIG. 1 is a high-level block diagram of a wireless transmitter in accordance with an embodiment.

FIG. 2 is a high-level block diagram of a digital pre-distortion system in accordance with an embodiment.

FIG. 3 is a graphical illustration of input power versus output power.

FIG. 4 is a block diagram of an address generation circuit and lookup table in accordance with an embodiment.

FIG. 5 is another block diagram of a digital pre-distortion system in accordance with an embodiment, illustrating further details of a loopback path.

FIG. 6A is a block diagram of a fractional delay calculation circuit in accordance with an embodiment.

FIG. 6B is a block diagram of a fractional delay calculation circuit in accordance with another embodiment.

FIG. 7A is a block diagram of a Farrow filter in accordance with an embodiment.

FIG. 7B is a block diagram of a Farrow filter in accordance with another embodiment.

FIG. 8 is a block diagram of a lookup table in accordance with an embodiment.

FIG. 9 is a flow diagram of a method in accordance with an embodiment for generation of a look up table.

FIG. 10 is a flow diagram of a method in accordance with another embodiment to use the look up table to pre-distort the transmit signal.

FIG. 11 is a block diagram of a representative integrated circuit in accordance with an embodiment.

FIG. 12 is a high level diagram of a network in accordance with an embodiment.

### DETAILED DESCRIPTION

In various embodiments, a power amplifier can be compensated digitally to pre-distort baseband signals before they are upconverted to RF levels. As mentioned above, this compensation is performed to reduce non-linearity effects of the PA. Embodiments provide a lookup table (LUT)-based solution for performing DPD compensation. As will be described herein, this LUT may be addressed via an addressing scheme that is based upon identification of a target output power level of the PA, reducing complexity and latency, by directly accessing a particular entry in the LUT, rather than performing a search of the LUT to find an entry.

PA linearity can degrade the error vector magnitude (EVM) and cause the transmit mask to be violated due to memoryless non-linearities. However, at wider channel bandwidths (e.g., 80 MHz), memory effects of the PA may also impact performance. These memory effects can be the result of internal capacitances in the PA, as well as slow response times of a voltage regulator-based power supply for the PA. In such embodiments, a hybrid approach to compensation may be implemented in which both LUT-based DPD and further compensation for memory effects using a filtering function and/or a memory polynomial are used. In such hybrid implementations, most of the PA DPD correction is realized by a LUT that models the PA characteristics, and memory effects are compensated by a finite impulse response (FIR) filter or small memory polynomial that operates in conjunction with the LUT function.

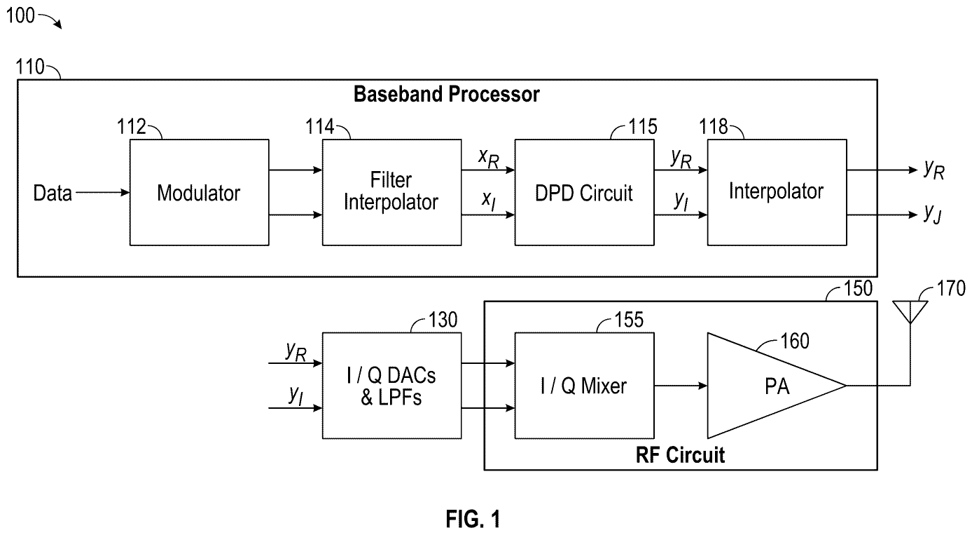

Referring now to FIG. 1, shown is a high-level block diagram of a wireless transmitter in accordance with an embodiment. As shown in FIG. 1, a portion of a device 100 is illustrated. In various embodiments, device 100 may be any type of wireless device, which can range from small Internet of Things (IoT) devices to larger wireless devices, such as smartphones, access points, tablet computers and so forth. In the high level diagram shown in FIG. 1, a transmit portion of wireless device 100 is illustrated. As shown, a baseband processor 110 operates digitally on information to be transmitted and provides it to further circuitry for conversion to analog form and further up-conversion to RF levels within an RF circuit 150, which further processes the RF signals and amplifies them to output a transmit RF signal, which is transmitted via an antenna 170.

As shown, incoming data, which may be received from additional circuitry of a baseband processor, such as a core or other processing circuitry, is provided to a modulator 112. Modulator 112 can generate various forms of modulation such as phase shift keying (PSK), quadrature amplitude modulation (QAM), orthogonal frequency division modulation (OFDM) and many other techniques that are known in the art. Additional operations may be performed here. For example, the modulated data can further be transformed into the time domain after frequency domain processing. The resulting signals can then be filtered and interpolated in a filter/interpolator 114. The resulting signals, which at this point are in complex format, are provided to a DPD circuit 115.

In various embodiments, DPD circuit 115 includes a lookup table (LUT) configured as described herein. Based on a power level of the input signal, a corresponding target output power level can be determined. In turn, this target output power level can be used to generate an address. This address in turn is used to access a given entry within the LUT to obtain compensation data. DPD circuit 115 then operates to apply this compensation data to the input signal. The resulting pre-distorted signals (still in complex form) are provided to an interpolator 118.

From there, the interpolated signals are converted to analog form in a digital-to-analog converter (DAC) and further filtering may be performed in one or more lowpass filters (LPFs) (block 130). The resulting analog signals, still in complex form and having the pre-distorted sample information, is provided to a complex mixer 155, which upconverts the signals to a desired RF level (e.g., 2.4 or 5 GHz). The RF signals are then amplified in a PA 160 before being transmitted via antenna 170. Although shown at this high level in the embodiment of FIG. 1, many variations and alternatives are possible.

Although not shown in FIG. 1, there may be digital circuitry after DPD circuit 115 to correct for I/Q mismatches in the analog/RF paths and DC offset to reduce LO feedthrough. For the 5 GHz band, DPD circuit 115 operates at a sample rate of 160 Megasamples per second (MSps) and the I/Q DACs operate at 160 Mbps and the LPF has a nominal corner frequency of approximately 20 MHz. In one or more implementations, the LUT (and FIR filter or memory polynomial, when a hybrid approach is used) can be implemented in dedicated register-transfer level (RTL) hardware.

In embodiments, the calibration data stored in the LUT and FIR filter coefficients can be determined during a calibration phase. Such calibration may be performed during manufacturing operations (e.g., as part of production testing (PTE)), and potentially again when an integrated circuit including the transceiver is incorporated into a wireless device. Further calibration can be performed dynamically in the field. For example, dynamic calibration can be performed during normal operation in the field as environmental conditions change.

DPD calibration can be performed by looping back a transmit (TX) signal to a receiver signal processing path of the transceiver. This loopback populates the LUT by using baseband equivalents (e.g., complex I and Q signals) of the PA input and output signals. The complex PA attenuation (or gain) is stored in the LUT for a given PA output (or input) power. The coefficients of the FIR filter (or memory polynomial) can be determined with a least mean square (LMS) adaptation method or a block method, to minimize the mean square error (MSE).

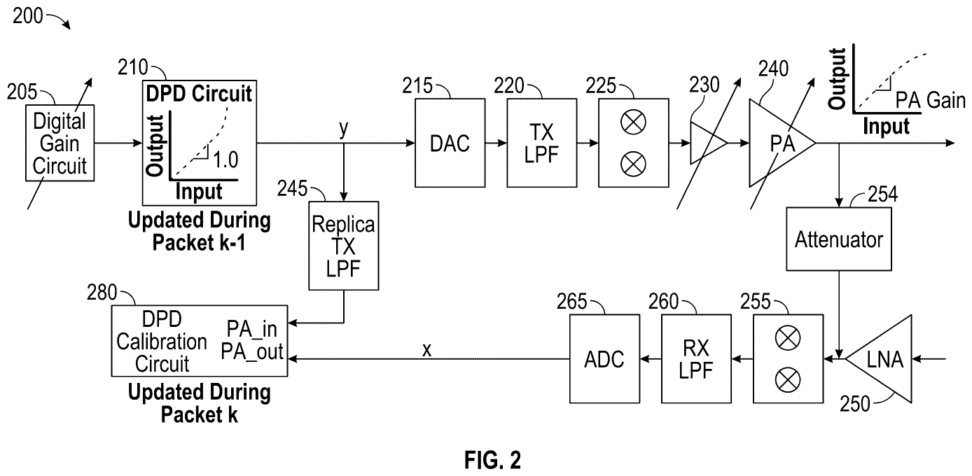

Referring now to FIG. 2 shown is a high-level block diagram of a DPD system in accordance with an embodiment, during transmission and calibration. In embodiments, while a packet is being transmitted, DPD parameters remain unchanged in the TX signal processing path to avoid unwanted transients in the TX signal. Since the PA typically exhibits compression at high power levels, the DPD creates an expansion, so that the overall response is linear. As the TX packet is being transmitted, the RX path loops back the down converted PA output signal. The equivalent PA input signal (at the replica filter output) and the PA output signal are stored in a memory. This data is processed, e.g., via firmware with optional hardware accelerators, which generates the compensation data for population into the LUT. This updated compensation data may then be used for performing compensation of future packets. For a hybrid approach, the firmware also determines the coefficients for the FIR filter (or memory polynomial in the more generalized case).

As shown in FIG. 2, device 200 includes a digital gain circuit 205. In embodiments, digital gain circuit 205 receives incoming data and provides a variable digital gain to the input samples before they are provided to a DPD circuit 210. DPD circuit 210 pre-distorts the samples using compensation data stored in a lookup table as discussed above. The pre-distorted samples are then converted to analog form in a DAC 215 (which can be implemented with complex (I and Q) DACs), and filtered in a LPF 220. The resulting filtered signals are then upconverted to an RF signal in complex mixer 225. Thereafter, signal levels may be adjusted in a variable gain amplifier (VGA) 230 and amplified via PA 240 for transmission. Signal levels can also be adjusted with the digital gain circuit.

Still referring to FIG. 2, loopback path circuitry also is present such that the amplified RF signal can be processed for purposes of performing DPD calibration as described herein. Thus, as shown, the output of PA 240 couples to an attenuator circuit 254 and is applied to the inputs of a complex mixer 255, bypassing a LNA 250. Attenuator 254 can be a passive circuit constructed with resistors, capacitors, inductors or a combination of all three. Depending upon implementation, much of the remaining loopback path circuitry may be of a receiver signal processing path of a combined transmitter and receiver (transceiver). In other cases, at least portions of the loopback circuitry can be implemented with dedicated circuitry.

As shown, attenuator 254 couples to complex mixer 255, which down converts the RF signals to a lower frequency. Filtering and digitization are performed in LPF 260 and ADC 265, respectively. Thus, a digitized signal corresponding to the PA output signal is provided to a DPD calibration circuit, along with the pre-distorted signal output from DPD circuit 210. More specifically, this signal is filtered in a replica transmit LPF 245. As will be described further herein, prior to the actual calibration that is performed between these input and output signals, an alignment process is performed to enable a given input sample to be processed with its corresponding output sample.

In an embodiment, replica filter 245 for the 5.0 GHz band can be implemented as a second-order 32 MHz Butterworth LPF with a first order filter in cascade having a 26 MHz pole. The replica has a sample rate of 160 MSps, and is implemented as a hardware-based digital filter.

In an embodiment, ADC 265 and DAC 215 each can be configured with 11 bits and a sample rate of 160 MHz. To achieve maximum SNR through the loopback path, both may operate near their maximum level.

PA characteristics (e.g., compression) can vary depending on the PA configuration (e.g., number of slices selected), PA load impedance (up to VSWR-3, any angle), temperature, power supply voltage, channel number, etc. Calibration can be performed dynamically according to a predetermined frequency, in some cases. Or calibration can occur when a given parameter (such as those discussed above) varies more than a given threshold.

At PTE, calibration can be performed for a nominal load (50 ohms) at room temperature, for the 2.4 GHz and 5 GHz PA's and at nominal supplies. In various implementations, one or more channels can be calibrated in each band. The resulting calibration data may be stored in a non-volatile memory (NVM), e.g., of the transceiver.

A given wireless device that incorporates the transceiver with this nominally stored compensation data may have an antenna design that differs from 50 ohms, even in the nominal condition, and thus a manufacturer of the wireless device can again perform the calibration routine to calibrate the PA with a particular antenna. The results of such calibration can be stored in the NVM, and in some cases such as where NVM storage is limited, this calibration data may overwrite the original calibration data.

In the field, when the TX powers up for the first time and begins to transmit, the initial calibration values from NVM are used. The TX packet specifications (EVM, TX mask) may or may not be met during this first transmission, so the loopback path and calibration can be enabled. A new set of calibration values (LUT & coefficients) dynamically determined in the field can then be used on future TX packets. As above, this updated calibration can be stored in NVM for future use. Further PA calibrations can be performed for temperature changes, potentially channel number and also based on a time interval. The time interval requirement may be based on the customer application to capture VSWR changes. For example, if the wireless device is implemented in a router or electric meter, VSWR changes should be quite infrequent. In contrast, a wireless device used in wearables could change rapidly as the individual moves. The criteria mentioned above are open loop measures.

In one embodiment, one or more quality monitors may be configured in the loopback path to periodically evaluate the EVM (or SNR or any other relevant metric) to determine whether a calibration is to occur. Referring to Table 1 below, shown are example criteria for triggering a calibration in accordance with an embodiment. As shown, in this embodiment calibration may be triggered responsive to a change in an environmental metric or parameter that exceeds a threshold level.

TABLE 1

| | Re-calibration criterion |
|---|---|
| Temperature | Δ T > 25 deg-C. |
| Channel # | Δ f > 200 MHz |
| Time Interval | 5-60 sec |
| Quality monitor | EVM / SNR falls below threshold |

Ideally, calibration via the loopback path during a TX packet is completed before the next TX packet is transmitted, using the updated compensation value, guaranteeing that the EVM and TX mask for the next packet will meet specifications. Thus, a calibration performed during a packet k results in updated compensation data stored in a lookup table that can be used for compensation of a following packet k+1. However, in some implementations, the computations to create the LUT are large and as such, updates may not be applied until a later packet (e.g., packet k+3). In such cases, one or more of the thresholds in Table 1 can be reduced, so that device EVM or TX mask are not violated. Note that calibration does not need the entire TX packet before processing can occur, and an entire packet is not needed to fill the LUT or converge the coefficients.

If an implementation incurs more calibration time such that updated values are not ready, the transmitter can continue to transmit with prior calibration values (although this may risk violating EVM or TX mask). In other cases, calibration can be performed more frequently than specified in Table 1, and/or where a quality monitor exists, re-calibration can be performed before the PA falls out of specification.

In order for the PA to produce the desired output power for a given input power, the DPD process increases the amplitude of the input signal so that even with soft clipping, the desired output power is achieved. In various embodiments to reduce searching time within a lookup table, a PA transfer characteristic is adapted so that a desired output power is the input signal multiplied by an ideal gain (typically 1.0), and the input DPD is found.

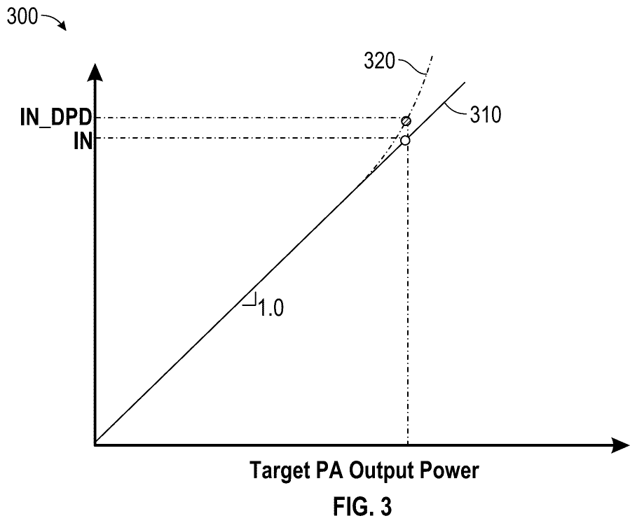

This transfer characteristic is shown in graphical illustration 300 of FIG. 3, in which the target output power of the PA is illustrated on the x-axis, and the input DPD is illustrated on the y-axis. As shown in FIG. 3, an idealized transfer function 310 demonstrates a linear response of a PA, while curve 320 illustrates an actual transfer response. Thus to achieve a target PA output power level, DPD compensation is provided to the input signal to thus increase its magnitude.

With this arrangement, address generation circuitry may be configured to map the PA output (or input) power to an address within the LUT. Thus the LUT may be configured having a plurality of entries (rows) that are indexed by the PA output (or input power).

Since the LUT and associated DPD circuit is used to take an I/Q input signal and calculate a pre-distorted I/Q output sample at a rate of 160 MSps, the hardware does not have time to search the LUT for the correct row of data to use. Thus addressing of the LUT rows can be performed as a deterministic function of the PA output (or input) power.

In an embodiment, an address generation circuit for the LUT is configured to generate an address for accessing the LUT using steps in the targeted output power. In an embodiment, the LUT may have the following characteristics: output power range of approximately 0-40 dB; uniform steps across the entire range, with coarse steps of approximately 3.0103 dB and fine steps of 3.0103 dB/8 (=0.3762875 dB). With this LUT configuration, the address generation circuit may be configured to perform a two-step RAM address decoding to generate an address for accessing the LUT.

In an embodiment, the LUT can be constructed as a matrix with 2 columns in which a given row is accessed using a generated address that is based on the target output power of the PA for a given sample. Column 1 contains the real part of PA's attenuation and column 2 contains the imaginary part of the PA's attenuation for a given power level. Rows of the matrix thus capture different output magnitudes and corresponding complex PA attenuation. In a particular implementation, rows are designed such that input power increments can be stepped in 3.01/8=0.376 dB steps over a 30-40 dB range, for example. In one or more implementations, the address of the row corresponds to the desired output power of the PA and the contents of the row include the PA attenuation at that power level. Using PA attenuation, rather than gain, simplifies computations (e.g., when the DPD is applied at the TX side at 160 MSps). In one or more implementations, the LUT may have rows that store attenuation values that are spaced logarithmically, rather than linearly (e.g., each entry may be spaced apart by decibel steps).

Referring now to Table 2, shown is a lower portion of LUT address decoding based on relative output power of the PA.

TABLE 2

| | | Coarse | Fine | Coarse | | |
|---|---|---|---|---|---|---|
| | Total Linear | Power | FACTOR | RAM | Fine RAM | Total RAM |
| Power(dB) | Power | (linear) | Power | Address | address | address |
| 0 | 1 | 1 | 1 | 0 | 0 | 0 |
| 0.376 | 1.091 | 1 | 1.091 | 0 | 1 | 1 |
| 0.753 | 1.189 | 1 | 1.189 | 0 | 2 | 2 |
| 1.129 | 1.297 | 1 | 1.297 | 0 | 3 | 3 |
| 1.505 | 1.414 | 1 | 1.414 | 0 | 4 | 4 |
| 1.881 | 1.542 | 1 | 1.542 | 0 | 5 | 5 |
| 2.258 | 1.682 | 1 | 1.682 | 0 | 6 | 6 |
| 2.634 | 1.834 | 1 | 1.834 | 0 | 7 | 7 |
| 3.01 | 2 | 2 | 1 | 8 | 0 | 8 |
| 3.387 | 2.181 | 2 | 1.091 | 8 | 1 | 9 |
| 3.763 | 2.378 | 2 | 1.189 | 8 | 2 | 10 |
| 4.139 | 2.594 | 2 | 1.297 | 8 | 3 | 11 |
| 4.515 | 2.828 | 2 | 1.414 | 8 | 4 | 12 |
| 4.892 | 3.084 | 2 | 1.542 | 8 | 5 | 13 |
| 5.268 | 3.364 | 2 | 1.682 | 8 | 6 | 14 |
| 5.644 | 3.668 | 2 | 1.834 | 8 | 7 | 15 |
| 6.021 | 4 | 4 | 1 | 16 | 0 | 16 |
| 6.397 | 4.362 | 4 | 1.091 | 16 | 1 | 17 |
| 6.773 | 4.757 | 4 | 1.189 | 16 | 2 | 18 |

As shown in Table 2, the first row represents the PA's minimum output power (0 dB), which corresponds to a coarse address of 0x0 and a fine address of 0x0. Although the PA output power in column one of Table 2 is shown in dB, decibels are never actually computed. The coarse address is designed so that shifts can be performed instead of multiplies (or divides).

In an address generation process, first the targeted output power is computed by summing the square of the real and imaginary parts of the PA input sample and then multiplying by the ideal linear gain magnitude (for a normalized LUT, this will be 1.0). This targeted output power is compared in a digital comparator against a first threshold to generate a coarse power level and corresponding coarse address bits of a RAM address. In turn, this coarse power level is divided by an integer value (e.g., 1, 2, 4, etc.) to yield a fine power level. The fine address is then determined by comparing this fine power level to a second threshold in another digital comparator.

The final RAM address is generated by summing the coarse and fine addresses. For flexibility, the coarse and fine thresholds for the address comparators can be programmed with hardware registers.

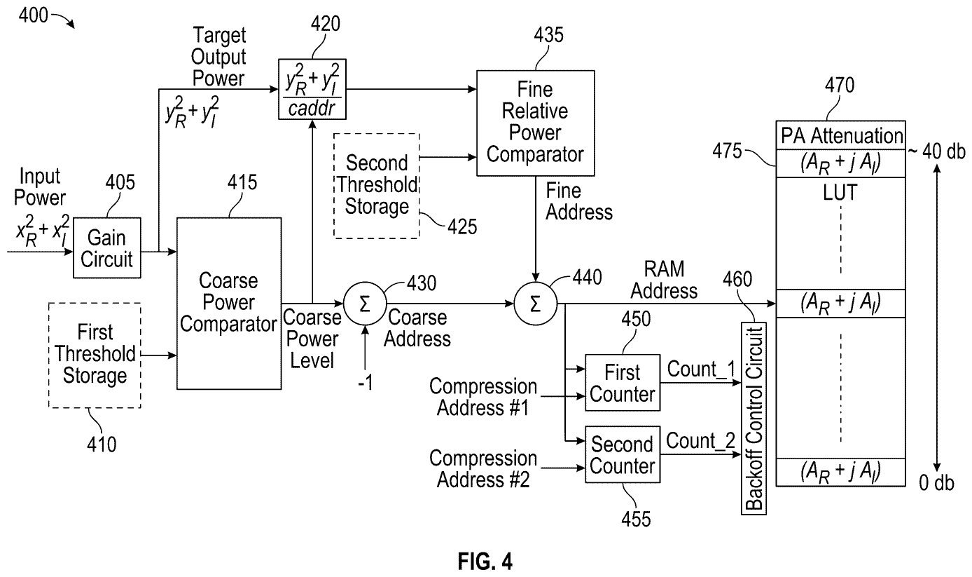

Referring now to FIG. 4, shown is a block diagram of an address generation circuit and LUT in accordance with an embodiment. As shown in FIG. 4, an apparatus 400 includes address generation circuitry and a LUT 470, along with associated control circuitry. As illustrated, an incoming complex signal (X_{R}+X_{I}) is received, and its power is calculated (as a sum of squares). This input power value is provided to a gain circuit 405, which provides a nominal gain level to obtain a target output power (Y²_{R}+Y²_{I}). Thus in gain circuit 405, the input power is computed and scaled by the nominal attenuation of LUT 470, and in an embodiment in which LUT 470 is normalized to 1.0, no multiply is needed to determine the targeted output power of the PA.

The target output power is decoded by the two-step address decoding circuit shown in FIG. 4 to locate the PA's complex attenuation at this output power level. As shown, the target output power level is provided to a first comparator 415, which is implemented as a coarse power comparator, which compares this target output power level to a first threshold obtained from a first threshold storage 410 (e.g., a register, which may be a programmable value set by firmware). As such, comparator 415 outputs a coarse power level which may be an integer. As shown, this coarse power level is provided to a calculation circuit 420, which divides the target output power by this coarse power level. Via a first summer 430, the coarse power level is transformed into a first portion of an address, namely, a coarse address.

As further shown, the divided value output from calculation circuit 420 is provided to a second comparator 435, which is implemented as a fine relative power comparator, which compares this divided output power level to a second threshold obtained from a second threshold storage 425 (e.g., a register, which may be a programmable value set by firmware). As such, comparator 435 outputs a fine power level. The resulting fine address is summed with the coarse address in a summer 440 to generate the address that is used to select a given entry within LUT 470. In an embodiment, LUT 470 may be implemented as a small dedicated RAM or using individual flip-flops (FF's).

As shown in the high level of FIG. 4, LUT 470 includes a plurality of entries 475, each of which includes a PA attenuation value, namely a complex value. In an embodiment, this complex value may be four bytes wide, with two bytes for the real component and two bytes for the imaginary component, each stored in a column (e.g., field) of a given row (e.g., entry). Although shown as having a range of approximately 40 dB, other ranges are possible. Also in implementations in which LUT 470 is configured to store the complex attenuation of the PA, rather than its complex gain, the number of computations may be reduced.

As further shown, the address also is provided to a plurality of counters 450, 455, each of which increments a given count value if the address (which as described above is indicative of a given target output power level) exceeds a threshold value. In various implementations, these thresholds can be programmed by firmware. The counts, in turn, are provided to a backoff control circuit 460, which may control a gain of the transmit path. Backoff can be applied as a gain change in the digital domain, baseband analog domain or in the RF domain. For example, when the counts exceed a given one or more thresholds, gain may be reduced to avoid compression of the PA. Although shown at this high level in the embodiment of FIG. 4, many variations and alternatives are possible.

Referring to Table 3, shown are operations performed in accordance with an embodiment (with or without interpolation) to compute a DPD-adjusted value for a given input sample when transmitting. In general, based on target output power, an address is determined and used to access a given attenuation value, which is then multiplied by the complex input signal to obtain the LUT-based DPD input sample. If the LUT has fine resolution in the PA output power, the algorithm to generate the DPD is adequate. However, if memory size limits the LUT resolution (in the number of rows), then interpolation between rows can be used to determine the complex attenuation of the PA, all of which is shown in Table 3.

TABLE 3

| | | No |
|---|---|---|
| | Interpolation | Interpolation |
| 1) Compute input sample power: | Multiply: 2 | Multiply: 2 |
| ${X}_{R}^{2} + {X}_{I}^{2}$ | Addition: 1 | Addition 1 |
| 2) Compute desired PA output power: | Multiply: 0 | Multiply: 0 |
| $( {X}_{R}^{2} + {X}_{I}^{2} ) * {G}_{ideal}$ | Addition: 0 | Addition 0 |
| Assume G_{ideal} = 1 | | |
| 3) Use LUT address that is closest to target | | |
| output power and obtain PA complex | | |
| attenuation | | |
| A₀ | | |
| 4. Use LUT address that is next closest to | | |
| target output power and obtain PA complex | | |
| attenuation: | | |
| A₁ | | |
| 5. Interpolate between 2 table entries from 3) | | |
| & 4) | | |
| $α = \frac{{G}_{ideal} * ( {X}_{R}^{2} + {X}_{I}^{2} ) - {PA}_{{power}_{1}}}{{PA}_{{power}_{0}} - {PA}_{{power}_{1}}}$ | | |
| $α = \frac{{G}_{ideal} * ( {X}_{R}^{2} + {X}_{I}^{2} ) - {PA}_{{power}_{1}}}{output power step size}$ | Multiply: 1 Addition: 1 | |
| A_{Target} = αA₀ + (1 − α)A₁ | Multiply: 4 | |
| | Addition: 3 | |
| 6. Compute input signal with DPD applied: | Multiply: 4 | Multiply: 4 |
| [(X_{R} + jX_{I})]G_{ideal} [A_{Target-R} + jA_{Target-I}] | Addition: 2 | Addition: 2 |
| Total: | Multiply: 11 | Multiply: 6 |
| | Addition: 6 | Addition: 3 |

In the ideal world, the LUT can be constructed with all samples that exist in the transmit packet; however, there is inadequate memory in the loopback path to store and compute all the data. Instead of the entire packet, the maximum number of PA input and output samples can be limited samples to approximately 1024, in an embodiment. With this limited data set, the likelihood of sampling the maximum peak amplitude is quite low. The maximum 12 dB peak to RMS for an OFDM signal only occurs with a probability of 1e-6, so with 1024 samples, it will be missed most of the time.

Note that during LUT construction an additional column may be included that maintains a count of how many samples were used to create the PA attenuation for a given output power level. Having this additional count information permits computing a weighted average of two LUTs to generate a new LUT that is based on more data points. With a maximum of 1024 samples for LUT construction, use of multiple LUTs and weighted averaging provides a LUT that over several iterations will more accurately model the PA compression characteristics. The compression characteristics can be modeled with complex numbers in cartesian or polar (e.g., AM-AM and AM-PM) formats.

In various embodiments, DPD can only linearize the PA characteristic for power levels below a saturation power level (Psat). If the targeted output power equals or exceeds Psat (or another criteria such as the 2 dB compression point), the system can be alerted so that in subsequent packets, the transmitted power level can be reduced.

In an embodiment, during packet transmission, counter 450 is incremented each time the TX power exceeds the 2 dB compression point of the PA. Prior to the next packet transmission, the counter is read, and may be used to determine whether and how to adjust PA power based on how many times the 2 dB compression point is exceeded. The determination to backoff also takes into account a modulation and coding scheme (MCS) level, since a lower MCS level can tolerate more compression. In one or more implementations, second counter 455 and corresponding second threshold can be used to track even higher compression levels (e.g., 3 dB compression point). Since the LUT RAM address corresponds to the PA output power, the counter(s) simply increment whenever the TX signal accesses a RAM address above the 2 dB (3 dB) compression point, as the address directly corresponds to the PA output power.

Determination of appropriate thresholds can be determined based on LUT construction, as every row of the LUT corresponds to the attenuation (or gain) of the PA for that output power level. Firmware can read through the LUT and find at what RAM address the PA attenuation exceeds 1 dB or 2 dB or 3 dB. Firmware then programs that address into the RAM threshold comparator circuit(s). Note that different MCS levels may choose different thresholds at which to reduce transmit power. In general, Psat will vary with VSWR, temperature and power supply voltage levels, so as a new LUT is created, the LUT address threshold will be updated.

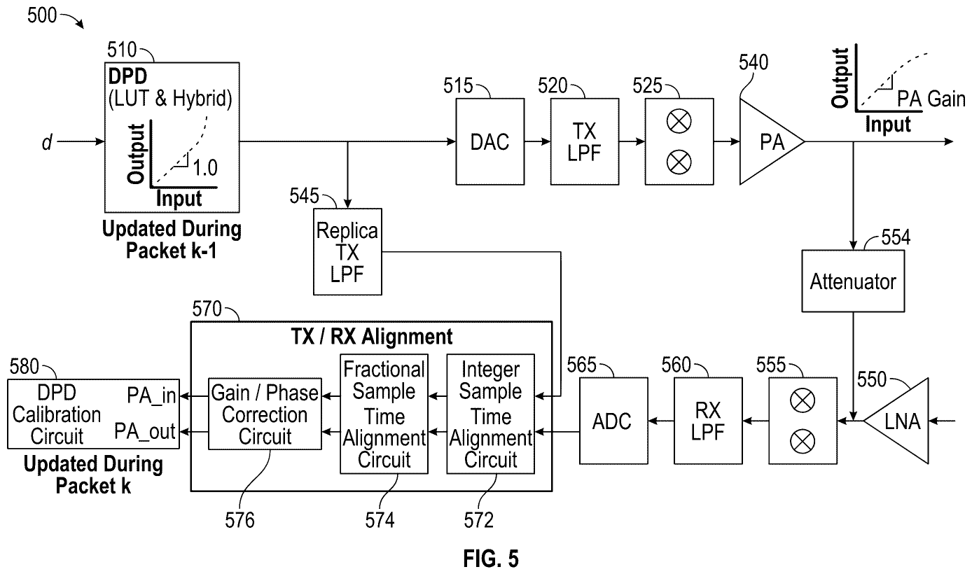

Referring now to FIG. 5, shown is another block diagram of a DPD system in accordance with an embodiment, illustrating further details of a loopback path. As discussed above, calibration is performed periodically by looping back the transmit signal through the receive path. In general, FIG. 5 illustrates the same circuitry as shown in FIG. 2, and to that extent, uses the same reference numerals (albeit of the “500” series).

Calibration uses the baseband equivalents of the PA input and output to update the DPD settings. The output of digital replica TX filter 545 is ideally the same as the complex output of analog TX filter 520, and thus the baseband equivalent of the PA input. On the receive side, the complex output of ADC 565 is the baseband equivalent of the PA output.

In certain implementations, the calibration process is primarily firmware based, but in some cases certain hardware accelerators can be used. The major functions during calibration are: (i) time alignment; (ii) complex gain scaling; (iii) LUT population; and (iv) coefficient convergence for the hybrid DPD augmentation. Whenever the loopback path is activated all four steps are performed, even though time-alignment may remain unchanged.

In one or more embodiments, PA input and output complex samples can be stored in RAM and then used for determining compensation values. In an embodiment, there may be 1024 samples obtained for both input and output data. As a transmit packet has many more than 1024 samples, certain portions of a packet may be identified to obtain the best samples. More specifically, for calibrating DPD, samples in the middle or end of the packet during a data field portion can be used, since these samples may have a highest peak-to-RMS ratio.

Prior to adjusting any DPD parameters, the transmit and receive signals are precisely aligned in time. The goal is to have the real (imaginary) parts of the PA transfer characteristics match as closely as possible and with a nominal gain of approximately 1.0. In an embodiment, alignment is performed in three stages: (1) integer time alignment; (2) fractional time alignment; and (3) gain/phase alignment.

As further shown in FIG. 5, alignment circuit 570 is configured to align samples between the input and output power paths, so that DPD calibration circuit 580 may operate on these corresponding samples. As shown, alignment circuit 570 includes three stages of alignment circuitry, including an integer alignment circuit 572, a fractional alignment circuit 574, and a gain/phase correction circuit 576. In one or more embodiments, a single hardware correlator implementation can be used in serial time by these different circuits to perform alignment to thus align input and output samples.

The first stage of alignment uses correlation of the PA input and output to align the signals to the closest sample boundary. For a 160 MSps rate, the time alignment resolution will be 6.25 nsec. In different implementations, as few as 128 samples may be adequate, and at least 256 samples is preferred.

In an embodiment, integer time alignment can be implemented with a fixed delay and a variable delay. Specifically, there is a fixed delay in the loopback path, which can be known from simulation or laboratory evaluation. A correlation as shown in a given one of Equations 1 and 2 is used to find the integer variable alignment. Specifically Equation 1 is as follows:

$$maximize with i [ β {\sum }_{k = 0}^{K} \vert {S}_{R} ( n - k - i ) \vert \vert {S}_{T} ( n - k ) \vert ] ;$$

and Equation 2 is as follows:

$$maximize with i [ {\vert β {\sum }_{k = 0}^{K} {S}_{R} ( n - k - i ) {S}_{T}^{*} ( n - k ) \vert}^{2} ] .$$

In Equations 1 and 2, S_{R} and S_{T} are the received (PA output) and transmitted (PA input) samples, respectively. In an embodiment, the search for alignment is estimated over a pre-defined window (e.g. +/−20 samples). The optional parameter B can be used to nominally equalize the amplitude of the signals prior to alignment to lower dynamic range requirements of the computations.

To optimize DPD calibration, time alignment finer than a resolution of 6.25 nsec is needed. To obtain virtually infinite resolution time alignment, a Farrow filter approach is used. The Farrow filter is an FIR filter with unity gain and linear phase (i.e., a fixed delay) in the passband. The coefficients are modified to vary the delay while maintaining unity gain.

A constant delay can be inserted into the path corresponding to the PA input signal and the fractional variable delay is placed in the PA output path that is looped back. In an embodiment, the variable delay path can be implemented with two Farrow filters (one real, one imaginary) whose delay can be varied with the parameter μ. Depending on implementation, μ can vary from −0.5 to +0.5 of the sample period. The fixed delay path corresponds to a Farrow filter with ρ=0, but the number of computations (or hardware) is reduced with a basic FIR structure.

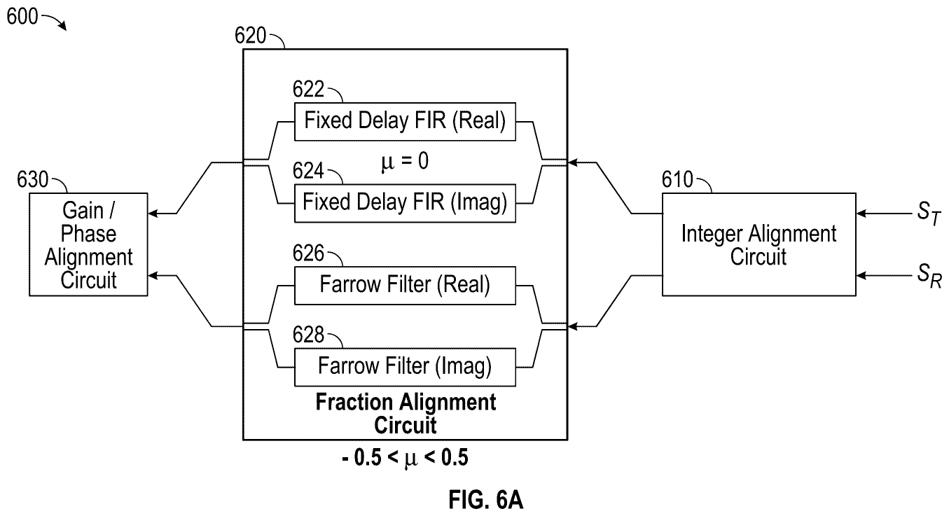

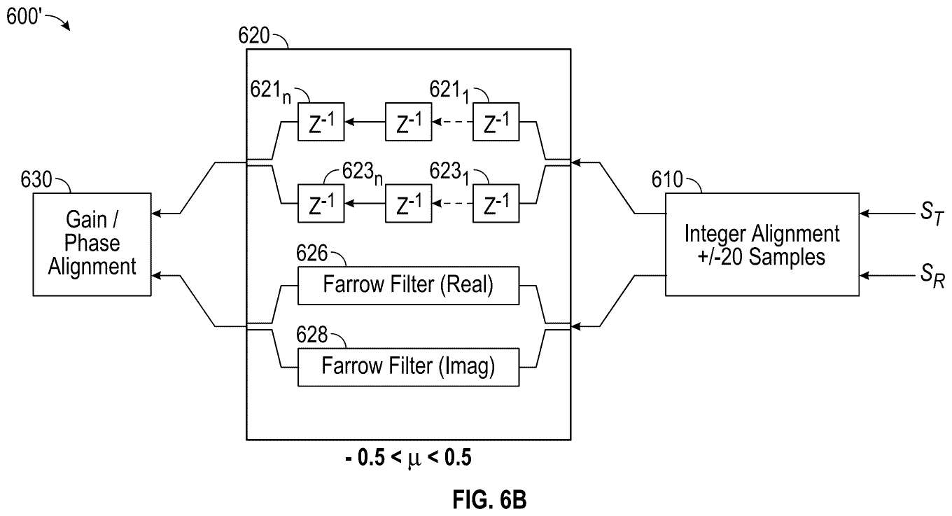

Referring now to FIG. 6A, shown is a block diagram of a fractional delay calculation circuit in accordance with an embodiment. In FIG. 6A, an apparatus 600 includes a fractional delay circuit 620, disposed between an integer alignment circuitry 610 and a gain/phase alignment circuit 630. In the high level view shown in FIG. 6A, integer alignment circuit 610, which may search on approximately +/−20 samples, provides corresponding integer-aligned transmit and receive samples (S_{T} and S_{R}) to circuit 620. As illustrated, fractional delay circuit 620 includes a pair of fixed delay finite impulse response (FIR) filters 622 (implemented for handling real signals) and FIR 624 (implemented for handling imaginary samples), which have a parameter μ=0. In turn, the loopback signals (namely the received samples) are provided to corresponding Farrow filters 626, 628 (which respectively operate on real and imaginary portions of these complex samples). As shown, these filters have a varying delay which in an embodiment may vary from −0.5 to 0.5 of a sample period (e.g., 6.25 nsec). The resulting fractionally-aligned samples are provided, in turn, to gain/phase alignment circuit 630.

The integer alignment is performed first by measuring sample correlation at the Farrow filter input. Fractional alignment is then performed by measuring the correlation at the Farrow filter output and then choosing the μ that maximizes the correlation.

In another embodiment, the FIR filter with fixed delay (implemented with μ=0 in FIG. 6A) can be eliminated to save computations. Referring now to FIG. 6B, shown is a block diagram of a fractional delay calculation circuit in accordance with another embodiment. In this arrangement, a fixed number of sample delays are included that closely approximates the Farrow filter delay with μ=0.

As shown in FIG. 6B, circuit 600′ has a fixed delay portion of fractional alignment circuit 620 that is implemented with a fixed number of delay elements for the real and imaginary paths (namely delay elements 621₁₋ₙ and 623₁₋ₙ). In other aspects, circuit 600′ may be implemented the same as circuit 600 discussed above.

The correlation measurements for both integer and fractional alignment are then made at the output of the fractional alignment circuit 600′. In an embodiment, the procedure is as follows: (1) set μ=0; (2) measure integer alignment at the Farrow filter output and find the optimal integer delays to insert based on correlation measurements; and (3) vary μ from −0.5 to +0.5 to determine the best fractional delay.

The variable delay Farrow filter can be constructed with various topologies, but it implements the same basic equation as shown in Equation 3:

$$y ( n ) = {\sum }_{k = 1}^{N} x ( n - k ) [ {c}_{0} ( k ) + μ {c}_{1} ( k ) + {μ}^{2} {c}_{2} ( k ) + {μ}^{3} {c}_{3} ( k ) ] .$$

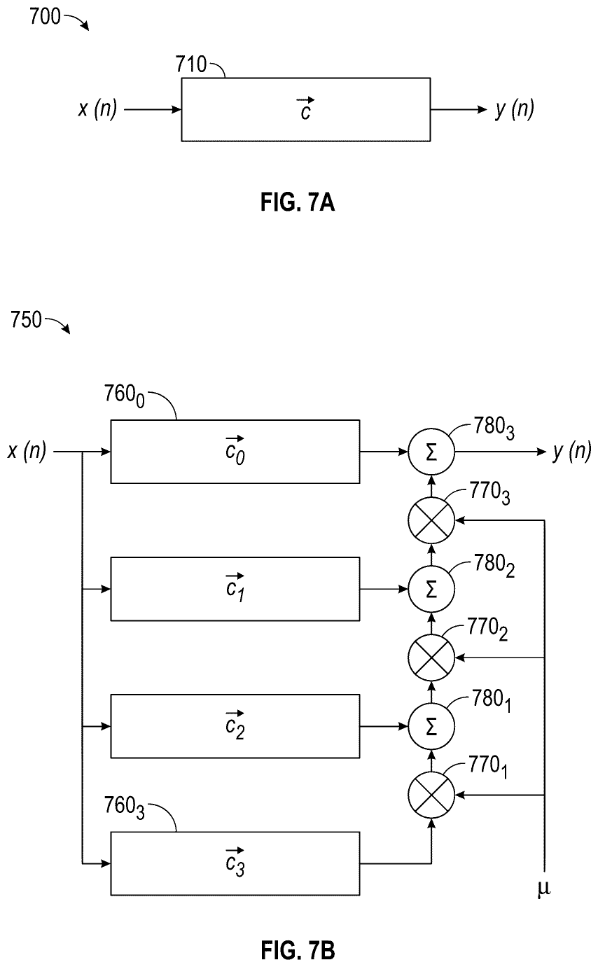

In Equation 3, y is the filter output, x is the filter input, and cx are the filter coefficients. Referring now to FIG. 7A, shown is a single real FIR filter having a single coefficient vector that is recalculated when a different value of fractional delay is required. In FIG. 7B, a Farrow filter is implemented with sub-filters, each with their respective constant coefficient vector.

Thus as shown in FIG. 7A, a first filter implementation 700 is implemented with a single real filter 710. In FIG. 7B, circuit 750 includes a plurality of sub-filters 760₀₋₃. As shown, the outputs of sub-filters 760₁₋₃ are multiplied and/or summed with each other and corresponding μ values via multipliers 770₁₋₃ and summers 780₁₋₃. Although shown at this high level in the embodiment of FIG. 7B, many variations and alternatives are possible.

There are many possible coefficient vectors to implement the Farrow filter. The number of sub-filters can be modified and the number of taps in each sub-filter can be varied. In an implementation, finite width coefficients may be used in the Farrow filter, with a total coefficient width of 12 bits (1 sign, 1 integer and 10 fractional).

In gain/phase alignment, the input and output of the PA are analyzed to determine a complex gain until the magnitude and phase of the input and output signals nominally match. These alignments correlate approximately equal amplitude and equal phase signals, and the LUT is automatically normalized to have an attenuation of 1.0 in the linear region of the PA.

In one embodiment, an iterative complex LMS adaptation approach may be used. In another embodiment, a gain G can be computed that minimizes the mean square error (MSE) between a block of N x( ) and y( ) samples. Such computation may be according to Equation 4,

$$G = \frac{{\sum }_{p = 1}^{N} x * ( p ) y ( p )}{{\sum }_{p = 1}^{N} x * ( p ) x ( p )} .$$

The number of real multiplies and additions are based on the number of samples. In an implementation, about 128 samples can be used, or equivalently 768 integer multiplications.

After alignment is performed, the transmit and loopback data are time aligned, phase aligned and amplitude equalized. The next step in the calibration process is to compute the PA's complex attenuation for each PA output sample. In an embodiment, this process is as follows:
1. Take a time-aligned PA input and output sample, and compute the PA's complex attenuation. (Attenuation=PA input/PA output).
2. Compute the PA output power for that sample.
3. Find the “bin” (i.e., corresponding row) in the LUT corresponding to that PA output power. Average the new complex attenuation with any prior attenuation in that “bin”. Note, a weighted summation is used since the attenuation in that row may have been averaged over many samples.
4. Obtain next input/output sample pair and repeat steps 1-3.
5. After all samples have been used,
   a. if any of the rows corresponding to higher output powers are empty, extrapolate the attenuations:
      i. Replicate the attenuation value from the last highest power measurement to the higher bins that have no data; or
      ii. If the attenuation of the last few occupied bins is increasing, linearly extrapolate unfilled bins by the same rate of increasing attenuation.
   b. If any intermediate rows have no data, interpolate the attenuation from adjacent rows.
   c. For very low power signals to remove noisy attenuation calculations, use the same attenuation level for the lowest 10 dB (e.g., lowest 25%) of the rows. (Can also just eliminate the lowest power rows from the RAM).
6. Finally, to smooth data across PA output powers, a 5 row moving average filter can be used across the PA attenuations stored in the LUT.

As the LUT is under construction, an extra column may be used to store the number of samples used to create the average PA attenuation for that PA output power.

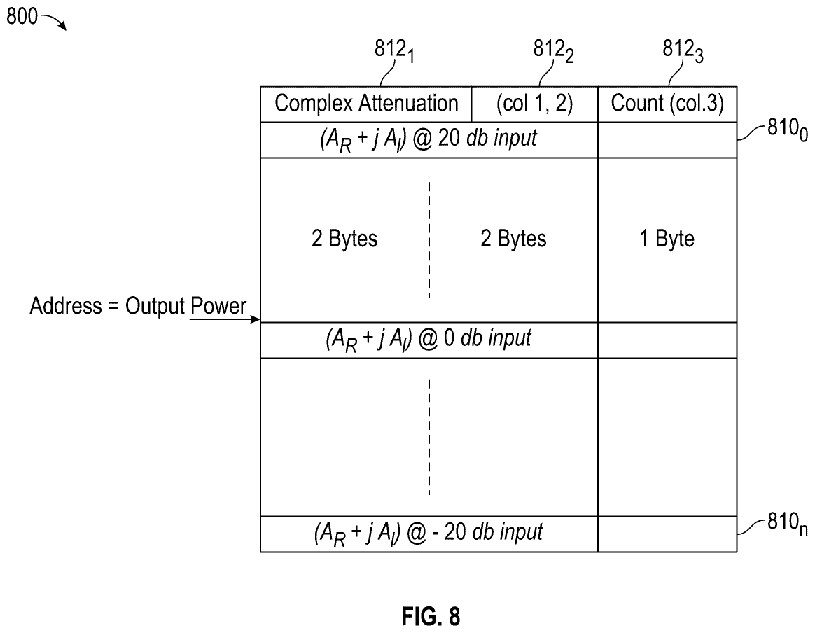

Referring now to FIG. 8, shown is a block diagram of a LUT in accordance with an embodiment. As shown, LUT 800 includes a plurality of entries 810₀₋ₙ, each having a plurality of fields 812₁₋₃. Note that this third entry (column) can be eliminated when placing in the high-speed memory of the TX path when used for a future packet.

As illustrated, the address of a row in LUT 800 is generated by a circuit that maps the target output power of the PA to the corresponding row. In each entry 810, a given PA complex attenuation value may be obtained, with separate two-byte values for the real and imaginary portions. Although shown with a particular range in FIG. 8, namely, 20 dB to −20 dB, in other implementations additional or different maximum and minimum target output power levels may be used.

In an implementation, to simplify hardware and firmware requirements for the LUT construction: (1) for time alignment of the PA input and output signals, only 256 samples are used from the center of the packet; (2) time alignment correlates the PA input with the conjugate of the PA output and the abs( )\hat{ }2 of each alignment test is computed until the maximum correlation is found; (3) for LUT construction, only 1024 samples are used from the center of the packet (after alignment has been performed); (4) Farrow filter steps are limited, e.g., to 0.125T (T/8 where T is the sampling period); (5) word widths can be limited to 2 bytes (with a sign bit, 0 integer bits, and 10 fractional bits).

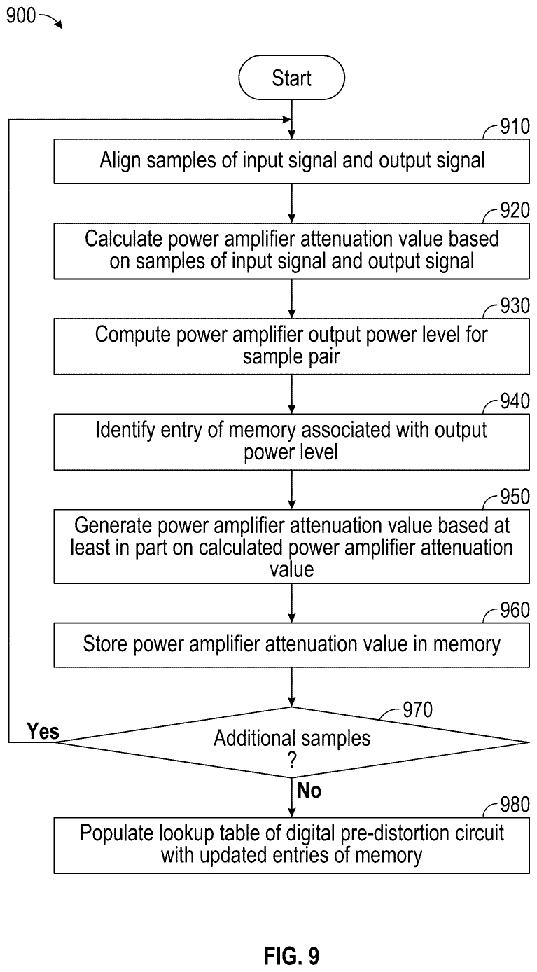

Referring now to FIG. 9, shown is a flow diagram of a method in accordance with an embodiment. More specifically, method 900 is a method for generating PA attenuation values when populating a lookup table for use in performing pre-distortion as described herein. Note that method 900 may be performed at various times, including at PTE (i.e., production test), incorporation of an IC having a transceiver as described herein into a wireless device and/or dynamically during normal operation in the field. In embodiments, method 900 may be performed by hardware circuitry alone and/or in combination with firmware and/or software.

As illustrated, method 900 begins by aligning samples of an input signal and an output signal (block 910). These samples of the input and output signals correspond to the input to the PA (received after baseband processing) and the output of the PA, as fed through a loopback path, as described herein. Once a pair of samples are aligned, control passes to block 920, where an attenuation value for the PA is calculated based on these samples (block 920). In an embodiment, the attenuation value can be computed by dividing the input to the PA by the output from the PA.

Next at block 930, the PA output power level for that sample pair is computed. In an embodiment, the output power may be computed by summing the individual squares of the real and imaginary components of the output signal sample. At block 940, an entry in the memory may be identified, where this entry is associated with the output power level. As discussed above, a target output power level can be used to generate an address for accessing the memory.

Then at block 950, a PA attenuation value may be generated based at least in part on the calculated PA attenuation value. That is, based on whether there already is an attenuation value stored in the accessed entry, the current PA attenuation value can be stored (when there is no previously stored value). Instead, when there is a previously stored value, the current attenuation value can be combined with the stored value, e.g., via an averaging operation. Note that in some cases, a weighted summation may be performed based on the number of samples. In any case, next at block 960, the determined PA attenuation value is stored into the identified entry.

Still referring to FIG. 9, at diamond 970 it is determined whether there are any further samples to be analyzed. If so, control passes back to block 910, as discussed above. Otherwise, the lookup table population may be completed by populating the table, e.g., stored in a memory with the updated entries (block 980). Depending upon when the method is performed, this table can be stored in an NVM, which may be included in the pre-distortion circuit or in another location such as a RAM. Although shown at this high level in the embodiment of FIG. 9, many variations and alternatives are possible.

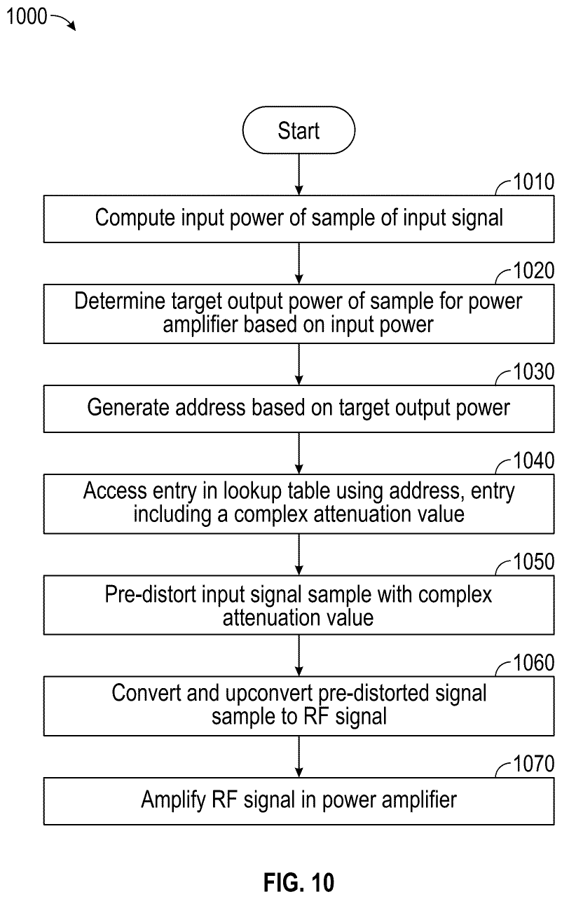

Referring now to FIG. 10, shown is a flow diagram of a method in accordance with another embodiment. More specifically, method 1000 is a method for pre-distorting signals before amplification in a PA using attenuation values stored in a lookup table as described herein. In embodiments, method 1000 may be performed by hardware circuitry alone and/or in combination with firmware and/or software.

As shown, method 1000 begins by computing an input power of a sample of an input signal (block 1010). This input signal is a complex baseband signal that may include message content that is generated in another portion of a baseband processor. Next at block 1020, based on the input power a target output power of this sample for the PA may be determined. From this target output power, at block 1030, an address may be generated for accessing the LUT. As discussed above in various embodiments, a two-step address generation process may be performed.

Still referring to FIG. 10, next at block 1040, an entry in the LUT may be accessed using the address. The entry includes a complex PA attenuation value. This attenuation value is used at block 1050 to pre-distort the input signal sample. In an embodiment, the attenuation value, along with any ideal gain value (which may be set to a nominal value of 1.0), is multiplied with the input signal. Thereafter, at block 1060, the resulting pre-distorted signal sample is converted to analog form and is upconverted to RF level. Finally at block 1070, the RF signal (including pre-distortion) is amplified in the PA. Although shown at this high level, many variations and alternatives are possible.

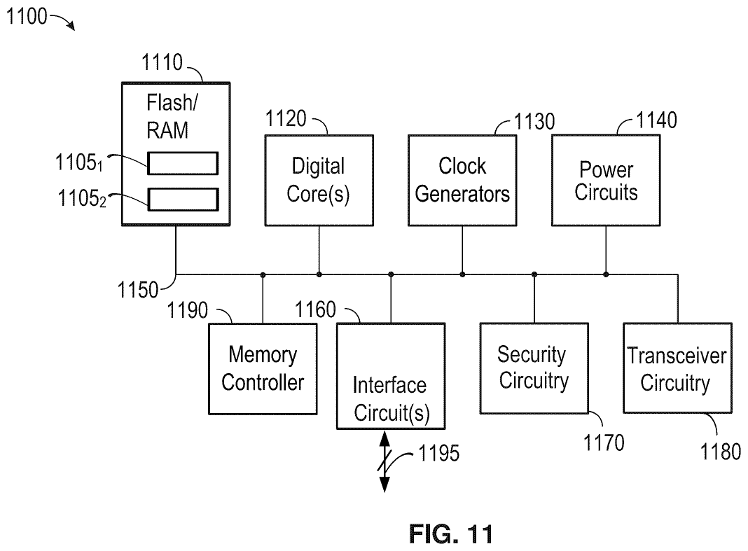

Referring now to FIG. 11, shown is a block diagram of a representative integrated circuit 1100 that includes DPD circuitry having a LUT generated and used as described herein. In the embodiment shown in FIG. 11, integrated circuit 1100 may be, e.g., a multi-mode wireless transceiver that may operate according to one or more wireless protocols or other device that can be used in a variety of use cases. In one or more embodiments, the circuitry of integrated circuit 1100 shown in FIG. 11 may be implemented on a single semiconductor die or implemented on separate dies for wireless communication, MCU compute, external flash and/or other IP blocks needed to perform various functionalities.

Integrated circuit 1100 may be included in a range of devices, but for purposes of discussion, it may be incorporated into an IoT device. In the embodiment shown, integrated circuit 1100 includes a memory system 1110 which in an embodiment may include volatile storage, such as RAM and non-volatile memory such as a flash memory. The flash memory is a non-transitory storage medium that can store instructions and data. In embodiments, this storage may store a LUT 1105₁ having entries including compensation information generated, e.g., during PTE. The flash memory is a non-transitory storage medium that also may store instructions, that when executed, cause DPD circuitry to perform dynamic updates to one or more LUTs as described herein. As further shown, memory 1110 includes a LUT 1105₂, which may be stored in the RAM and can include entries populated from the flash memory and/or dynamically generated and updated in the field as described herein. Integrated circuit 1100 also may include a memory controller 1190.

Memory system 1110 couples via a bus 1150 to one or more digital cores 1120, which may include one or more cores and/or microcontrollers that act as processing units of the integrated circuit, and which may execute an IoT end device application to control circuitry of the IoT device. In turn, digital cores 1120 may couple to clock generators 1130 which may provide one or more phase locked loops or other clock generator circuitry to generate various clocks for use by circuitry of the IC.

As further illustrated, IC 1100 further includes power circuitry 1140. Additional circuitry may be present depending on particular implementation to provide various functionality and interaction with external devices. Such circuitry may include interface circuitry 1160 which provides a digital communication interface with additional circuitry (such as another IC that can couple to IC 1100 via a link 1195). IC 1100 also may include security circuitry 1170 to perform wireless security techniques.

In addition, as shown in FIG. 11, transceiver circuitry 1180 may be provided to enable transmission and reception of wireless signals, e.g., according to one or more of a local area or wide area wireless communication scheme, such as Matter, Zigbee, Bluetooth, IEEE 802.11, IEEE 802.15.4, cellular communication or so forth. Understand while shown with this high level view, many variations and alternatives are possible.

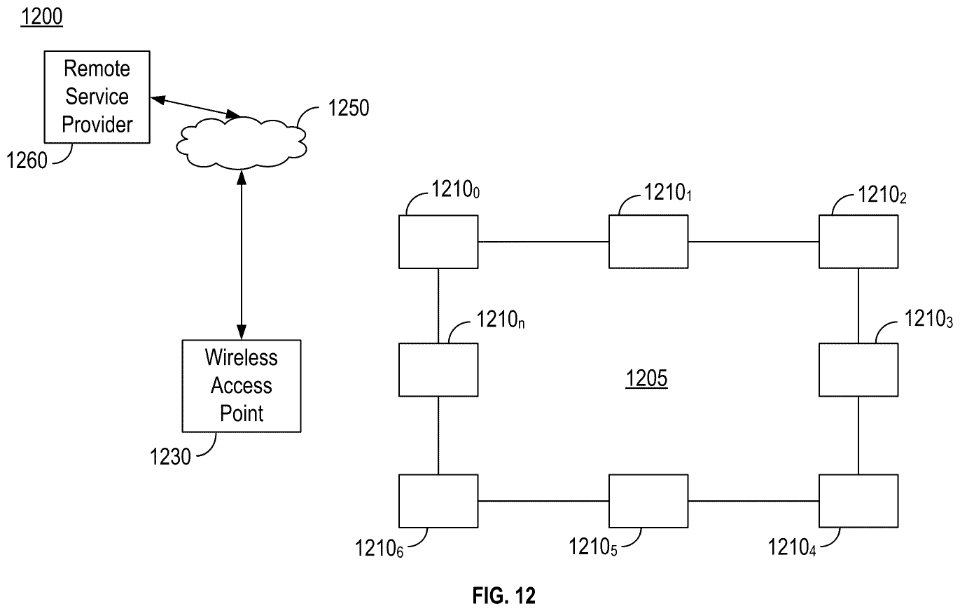

ICs such as described herein may be implemented in a variety of different devices as described above. Referring now to FIG. 12, shown is a high level diagram of a network in accordance with an embodiment. As shown in FIG. 12, a network 1200 includes a variety of devices, including IoT devices that may perform digital pre-distortion of baseband signals using a LUT generated and updated as described herein, to compensate for distortion of a PA. Understand that network 1200 includes other devices such as access points and remote service providers.

In the embodiment of FIG. 12, a wireless mesh network 1205 is present, e.g., in a building having multiple wireless devices 1210₀₋ₙ. As shown, wireless devices 1210, which may be IoT or other wireless devices, couple to an access point 1230 that in turn communicates with a remote service provider 1260 via a wide area network 1250, e.g., the Internet. Understand while shown at this high level in the embodiment of FIG. 12, many variations and alternatives are possible.

While the present disclosure has been described with respect to a limited number of implementations, those skilled in the art, having the benefit of this disclosure, will appreciate numerous modifications and variations therefrom. It is intended that the appended claims cover all such modifications and variations.

What is claimed is:

1. An apparatus comprising:
a baseband processor to generate a baseband signal;
a digital pre-distortion (DPD) circuit to pre-distort the baseband signal with compensation information obtained from a lookup table, the lookup table having a plurality of entries each to store a pre-distortion value, the lookup table to be addressed based on a target output power level of the baseband signal;
a converter to convert the pre-distorted baseband signal to an analog signal; and
radio frequency (RF) circuitry comprising:
a mixer to upconvert the analog signal to a pre-distorted RF signal; and
a power amplifier (PA) to amplify the pre-distorted RF signal.

2. The apparatus of claim 1, wherein each of the plurality of entries of the lookup table is to store the compensation information comprising a complex attenuation value.

3. The apparatus of claim 1, wherein each of the plurality of entries of the lookup table is to store the compensation information comprising a complex gain value.

4. The apparatus of claim 1, further comprising an address generator circuit to generate the address based on the target output power level.

5. The apparatus of claim 4, wherein the address generator circuit is to generate the address comprising a sum of a first portion and a second portion, wherein the address generation circuit is to:
generate the first portion based on a first comparison of the target output power level to a first value; and
generate the second portion based on a second comparison of a result of an operation between the target output power level and the first portion to a second value.

6. The apparatus of claim 1, further comprising at least one counter to maintain a count of samples of the baseband signal having the target output power level that exceeds at least one threshold.

7. The apparatus of claim 6, further comprising a control circuit to control a gain level of transmit circuitry of the RF circuit based at least in part on the count.

8. The apparatus of claim 1, further comprising a loopback circuit coupled to an output of the PA, the loopback circuit to generate a digital signal corresponding to the amplified RF signal.

9. The apparatus of claim 8, wherein the loopback circuit further comprises an alignment circuit to receive the digital signal and the pre-distorted baseband signal and to align the pre-distorted baseband signal with the digital signal.

10. The apparatus of claim 9, wherein the alignment circuit comprises:
an integer alignment circuit;
a fractional alignment circuit; and
a gain/phase alignment circuit.

11. The apparatus of claim 10, wherein the alignment circuit comprises at least one correlator, each of the integer alignment circuit, the fractional alignment circuit and the gain/phase alignment circuit to share the at least one correlator.

12. The apparatus of claim 1, wherein each of the plurality of entries is associated with the target output power level that is logarithmically spaced from adjacent entries.

13. The apparatus of claim 1, wherein the DPD circuit is to further pre-distort the baseband signal to compensate for a memory effect of the PA.

14. A method comprising:
computing, in a digital pre-distortion circuit of a transmitter, an input power of an input sample of a packet to be amplified and output from a power amplifier (PA) of the transmitter;
determining a target output power for the input sample based on the input power;
generating an address based on the target output power and accessing an entry in a lookup table using the address, the entry comprising a PA complex attenuation value associated with the target output power;
pre-distorting the input sample using the PA complex attenuation value;
upconverting the pre-distorted input sample to a radio frequency (RF) signal corresponding to the input sample; and
amplifying the RF signal via the PA to output an amplified RF signal.

15. The method of claim 14, wherein generating the address comprises:
determining a first portion of the address according to a first decoding; and
determining a second portion of the address according to a second decoding; and
combining the first portion and the second portion to generate the address.

16. The method of claim 14, further comprising:
accessing a second entry in the lookup table using the address, wherein the second entry is adjacent to the first entry.

17. The method of claim 14, further comprising:
determining an interpolated PA complex attenuation value based on the PA complex attenuation value of the entry and a second PA complex attenuation value of the second entry; and
pre-distorting the input sample using the interpolated PA complex attenuation value.

18. A computer readable storage medium comprising instructions that cause a processor to perform a method comprising:
calculating an attenuation value for a sample pair comprising an input sample to a power amplifier (PA) of a transceiver and an output sample from the PA, the output sample aligned with the input sample;
computing an output power level of the PA based at least in part on the input sample;
generating a PA attenuation value based at least in part on the calculated attenuation value; and
storing the PA attenuation value in an entry of a memory, the entry associated with the output power level.

19. The computer readable storage medium of claim 18, wherein generating the PA attenuation value comprises combining the calculated attenuation value with a stored attenuation value stored in the entry of the memory.

20. The computer readable storage medium of claim 18, wherein the method further comprises aligning the input sample with the output sample.

21. The computer readable storage medium of claim 20, wherein aligning the input signal with the output signal comprises:
integer aligning the input sample with the output sample;
fractionally aligning the input sample with the output sample; and
aligning the input sample with the output sample in at least one of gain or phase.

22. The computer readable storage medium of claim 18, wherein the method comprises:
updating a plurality of entries of the memory during transmission of a first packet from the transceiver; and
accessing one or more of the updated plurality of entries of the memory to provide digital pre-distortion to one or more samples of a second packet to be transmitted from the transceiver.

23. The computer readable storage medium of claim 18, wherein the method further comprises calculating the attenuation value, computing the output power level, and generating the PA attenuation value when a change in at least one environmental metric of the transceiver exceeds a threshold.
